(19) United States
(12) Patent Application Publication
(10) Pub. No.: US 2022/0216673 A1
(43) Pub. Date: Jul. 7, 2022

(54) Semiconductor Laser

(71) Applicant: Nippon Telegraph and Telephone Corporation, Tokyo (JP)

(72) Inventors: Erina Kanno, Tokyo (JP); Koji Takeda, Tokyo (JP); Takaaki Kakitsuka, Tokyo (JP); Shinji Matsuo, Tokyo (JP)

(21) Appl. No.: 17/605,504

(22) PCT Filed: May 16, 2019
(86) PCT No.: PCT/JP2019/019490

§ 371 Date: Oct. 21, 2021

(51) Int. Cl. H01S 5/125; H01S 5/12

(52) U.S. Cl. CPC H01S 5/125; H01S 5/124

(57) ABSTRACT

A length L₁ of a first distributed Bragg reflector in a waveguide direction, a length L₂ of a distributed feedback active region in the waveguide direction, a length L₃ of a second distributed Bragg reflector in the waveguide direction, and a position xₚₛ of a phase shift portion are set to satisfy correlations of xₚₛ=L₁+L₂×α, L₂(1−α)+L₃>xₚₛ, and 0.5<α<1. Further, the position xₚₛ is a position of the phase shift portion in the waveguide direction with an end portion thereof on the first distributed Bragg reflector side set as an origin.

### CROSS-REFERENCE TO RELATED APPLICATIONS

This application is a national phase entry of PCT Application No. PCT/JP2019/019490, filed on May 16, 2019, which application is hereby incorporated herein by reference.

### TECHNICAL FIELD

The present invention relates to a semiconductor laser used for a light source for an optical transmitter or the like.

### BACKGROUND

Various wavelength multiplexing light sources have been developed in order to perform transmission of a large amount of information using wavelength division multiplexing (WDM). In WDM, single-mode oscillation and oscillation wavelength control of a laser as a light source are important. For example, as a technique for realizing single-mode oscillation, there is a phase shift distributed feedback (DFB) laser (see NPL 1).

A phase shift DFB laser has a structure in which a diffraction grating inverts a phase thereof on the way (phase shift) and can oscillate at a Bragg wavelength of the diffraction grating. The Bragg wavelength is determined by a period of the diffraction grating. By manufacturing the diffraction grating using electron beam lithography technology, the period of the diffraction grating can be controlled with high accuracy. However, since oscillating light is emitted from both ends of an element in the above-mentioned phase shift DFB laser, the light emitted from one end portion thereof may not be used, and in this case, half of the light will be lost.

In order to solve the above-mentioned problems, a distributed reflector (DR) laser that is configured by connecting a distributed Bragg reflector (DBR) having a high reflectance to one end of a phase shift DFB laser to emit light from the other end thereof has been proposed (see NPL 2).

A DR laser in which DBRs are provided at both end portions of a phase shift DFB laser, a reflectance of one DBR is lowered with respect to the other DBR, and light is emitted from the one DBR has also been proposed (see NPL 3). In the configuration in which DBRs are provided on both sides, as compared with a configuration in which a DBR is provided on only one side, an oscillation threshold gain can be lowered, which is advantageous for oscillation of a short resonator laser having a large loss.

### CITATION LIST

### Patent Literature

PTL1—Japanese Patent Application Publication No. 2019-12769

### Non Patent Literature

NPL 1—K. Utaka et al., “λ/4-Shifted InGaAsP/InP DFB Lasers”, IEEE Journal of Quantum Electronics, Vol. QE-22, No. 7, pp. 1042-1051, 1986.
NPL 2—K. Ohira et al., “GaInAsP/InP distributed reflector laser with phase-shifted DFB and quantum-wire DBR sections”, IEICE Electronics Express, Vol. 2, No. 11, pp. 356-361, 2005.
NPL 3—K. Otsubo et al., “Low-Driving-Current High-Speed Direct Modulation up to 40 Gb/s Using 1.3-um Semi-Insulating Buried-Hetero structure AlGaInAs-MQW Distributed Reflector (DR) Lasers”, Proc./OFC/NFOEC, Paper OThT6, 2009.

### SUMMARY

### Technical Problem

Incidentally, an attempt to introduce WDM according to a wavelength multiplexing light source using the above-mentioned semiconductor laser technology not only in a metro network but also in an optical interconnect for short-distance communication such as between chips is being studied. In a case in which it is applied to this optical interconnect between chips, as is well known, low power consumption is important. However, no light source suitable for such an optical interconnect between chips has been reported at present. In the above-mentioned waveguide type laser, it is effective to shorten a length of an active region (active layer) in a waveguide direction for low power consumption, and this configuration is being anticipated.

In order for a laser having a short active layer length to satisfy oscillation conditions, it is important to increase a reflectance in a diffraction grating. In order to increase the reflectance, a coupling coefficient of the diffraction grating should be increased, but in a case in which a phase shift is applied to the diffraction grating to control an oscillation wavelength, spatial hole burning causes instability of an oscillation mode and deterioration of modulation characteristics. For that reason, a double-sided DR laser that can make an oscillation threshold gain lower than that of a DFB laser or a one-sided DR laser with the same coupling coefficient is advantageous for oscillation of a laser having a short active layer length.

However, the oscillation characteristics of double-sided DR laser is more strongly affected by manufacturing errors such as a deviation of an active layer that becomes a gain region than that of the DFB laser and the single-sided DR laser. Especially, in a case in which an active layer and an optical waveguide portion are made of different materials in order to make manufacturing simple, it is more strongly affected by manufacturing errors due to a difference in equivalent refractive index, which affects single mode products. In order to deal with this problem, a structure in which a position of a phase shift is devised has been proposed (see PTL 1).

However, the above-mentioned technique has a problem that an increase in threshold gain due to a diffraction grating loss becomes larger. In order for a laser having a short active layer length to satisfy oscillation conditions, it is necessary to increase a coupling coefficient of a diffraction grating, but generally, the loss increases as a coupling coefficient of a diffraction grating becomes larger. For this reason, in a laser having a short active layer length, it is important to inhibit the increase in threshold gain due to the diffraction grating loss.

Embodiments f the present invention have been made to solve the above problems, and an object thereof is to provide a phase shift distributed feedback laser having distributed Bragg reflectors provided on both sides, which can inhibit influences of manufacturing errors and enable stable single-mode oscillation without increasing a threshold gain.

### Means for Solving the Problem

A semiconductor laser according to embodiments of the present invention includes: an active layer formed on a substrate; a distributed feedback active region which is formed along the active layer and includes a first diffraction grating including a phase shift portion that shifts a phase of a diffraction grating; and a first distributed Bragg reflector and a second distributed Bragg reflector which are disposed continuously with the distributed feedback active region with the distributed feedback active region interposed therebetween, in which the first distributed Bragg reflector includes a first core layer which is formed continuously with the active layer in a waveguide direction and has a refractive index different from that of the active layer, and a second diffraction grating formed along the first core layer, the second distributed Bragg reflector includes a second core layer which is formed continuously with the active layer in the waveguide direction on a side opposite to the first core layer with the active layer interposed therebetween and has a refractive index different from that of the active layer, and a third diffraction grating formed along the second core layer, and a length L₁ of the first distributed Bragg reflector in the waveguide direction, a length L₂ of the distributed feedback active region in the waveguide direction, a length L₃ of the second distributed Bragg reflector in the waveguide direction, and a position xₚₛ of the phase shift portion in the waveguide direction with an end portion thereof on the first distributed Bragg reflector side set as an origin are set to satisfy correlations of xₚₛ=L₁+L₂×α, L₂(1−a)+L₃>xₚₛ, and 0.5<α<1.

In one configuration example of the above semiconductor laser, the distributed feedback active region includes a p-type semiconductor layer and an n-type semiconductor layer formed in contact with the active layer, an n-type electrode connected to the n-type semiconductor layer, and a p-type electrode connected to the p-type semiconductor layer.

In one configuration example of the above semiconductor laser, the p-type semiconductor layer and the n-type semiconductor layer are formed on the substrate in contact with a side surface of the active layer in a direction perpendicular to the waveguide direction.

In one configuration example of the above semiconductor laser, the p-type semiconductor layer and the n-type semiconductor layer are formed to interpose the active layer from above and below.

### Effects of Embodiments of the Invention

As described above, according to embodiments of the present invention, because the length L₁ of the first distributed Bragg reflector, the length L₂ of the distributed feedback active region, the length L₃ of the second distributed Bragg reflector, and the position xₚₛ of the phase shift portion are set to satisfy the correlations of xₚₛ=L₁+L₂×α, L₂(1−a)+L₃>xₚₛ, and 0.5<α<1, the phase shift distributed feedback laser having the distributed Bragg reflectors provided on both sides can inhibit influences of manufacturing errors and perform stable single-mode oscillation without increasing the threshold gain.

### BRIEF DESCRIPTION OF THE DRAWINGS

FIG. 1 is a configuration diagram showing a configuration of a semiconductor laser according to an embodiment of the present invention.

FIG. 2A is a perspective view showing a more detailed configuration of the semiconductor laser according to the embodiment of the present invention.

FIG. 2B is a cross-sectional view showing the configuration of the semiconductor laser according to the embodiment of the present invention.

FIG. 3A is a configuration diagram showing a state during manufacture of the semiconductor laser according to the embodiment of the present invention.

FIG. 3B is a configuration diagram showing a state during manufacture of the semiconductor laser according to the embodiment of the present invention.

FIG. 3C is a configuration diagram showing a state during manufacture of the semiconductor laser according to the embodiment of the present invention.

FIG. 3D is a configuration diagram showing a state during manufacture of the semiconductor laser according to the embodiment of the present invention.

FIG. 3E is a configuration diagram showing a state during manufacture of the semiconductor laser according to the embodiment of the present invention.

FIG. 3F is a configuration diagram showing a state during manufacture of the semiconductor laser according to the embodiment of the present invention.

FIG. 4 is a configuration diagram showing a state of deviation of the semiconductor laser according to the embodiment of the present invention.

FIG. 5 is a configuration diagram showing a state of deviation of the semiconductor laser according to the embodiment of the present invention.

FIG. 6 a characteristic diagram showing a relationship between an amount of deviation of a position of an active layer in a waveguide direction from a design value and a difference in threshold mode gain in a case in which a length of the active layer in the waveguide direction is formed to be 500 nm shorter than the design value in total.

FIG. 7 is a characteristic diagram showing a relationship between a diffraction grating loss and the threshold mode gain.

FIG. 8 is a characteristic diagram showing a relationship between an inclination of a graph in FIG. 7 and a that defines a position xₚₛ of a phase shift portion.

FIG. 9 is a cross-sectional view showing another configuration of the semiconductor laser according to the embodiment of the present invention.

### DETAILED DESCRIPTION OF ILLUSTRATIVE EMBODIMENTS

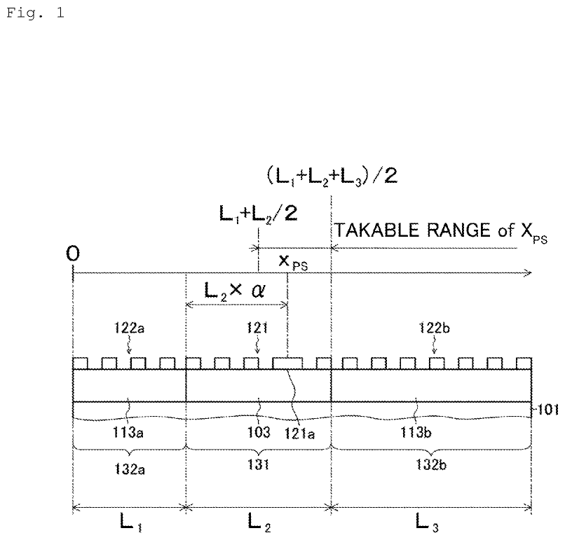

Hereinafter, a semiconductor laser according to an embodiment of the present invention will be described with reference to FIG. 1. This semiconductor laser includes a distributed feedback active region 131, a first distributed Bragg reflector 132a and a second distributed Bragg reflector 132b that are disposed continuously with the distributed feedback active region 131. This semiconductor laser is a so-called DR laser. The first distributed Bragg reflector 132a and the second distributed Bragg reflector 132b are disposed continuously with the distributed feedback active region 131 with the distributed feedback active region 131 interposed therebetween in a waveguide direction.

The distributed feedback active region 131 includes an active layer 103 on which a first diffraction grating 121 is formed. Further, the active layer 103 extends a predetermined length in a light emitting direction, and the first diffraction grating 121 is formed on the active layer 103 in the distributed feedback active region 131 in the direction in which it extends. The first diffraction grating 121 is formed along the active layer 103 and includes a phase shift (λ/4 shift) portion 121a that shifts a phase of the diffraction grating. The phase shift portion 121a is set such that a Bragg wavelength of the first diffraction grating 121 becomes uniform. Also, in the present example, the first diffraction grating 121 is formed on the active layer 103.

Further, the first distributed Bragg reflector 132a includes a first core layer 113a on which a second diffraction grating 122a is formed. The first core layer 113a is formed continuously with the active layer 103 in the waveguide direction.

Further, the second diffraction grating 122a is formed along the first core layer 113a. Similarly, the second distributed Bragg reflector 132b includes a second core layer 113b on which a third diffraction grating 122b is formed. The second core layer 113b is formed continuously with the active layer 103 in the waveguide direction on a side opposite to the first core layer 113a with the active layer 103 interposed therebetween. Also, the third diffraction grating 122b is formed along the second core layer 113b.

The first core layer 113a and the second core layer 113b have refractive indexes different from that of the active layer 103. In addition, in the present example, the second diffraction grating 122a is formed on (an upper surface of) the first core layer 113a, and the third diffraction grating 122b is formed on (an upper surface of) the second core layer 113b. Further, in the semiconductor laser, a non-reflective film (not shown) is formed on an output end surface on the first distributed Bragg reflector 132a side.

In addition, a length L₁ of the first distributed Bragg reflector 132a in the waveguide direction, a length L₂ of the distributed feedback active region 131 in the waveguide direction, a length L₃ of the second distributed Bragg reflector 132b in the waveguide direction, and a position xₚₛ of the phase shift portion 121a are set to satisfy correlations of xₚₛ=L₁+L₂×α, L₂(1−a)+L₃>xₚₛ, and 0.5<α<1. Further, the position xₚₛ is a position of the phase shift portion 121a in the waveguide direction with an end portion thereof on the first distributed Bragg reflector 132a side set as an origin. For example, the position xₚₛ in a case of α=1 is a position adjacent to the other end of the distributed feedback active region 131, in other words, a boundary between the first diffraction grating 121 and the third diffraction grating 122b. Also, for example, the position xₚₛ in a case of α=0.5 becomes a central portion of the distributed feedback active region 131.

As will be described later, when the position of the phase shift portion 121a is set to the boundary (α=1) between the second distributed Bragg reflector 132b and the distributed feedback active region 131, influences of manufacturing errors can be inhibited, but an oscillation threshold gain increases due to a diffraction grating loss. On the other hand, when the position of the phase shift portion 121a is set to a center (α=0.5) of the distributed feedback active region 131, it is possible to inhibit an increase in the oscillation threshold gain due to the diffraction grating loss, but there is a risk of multi-mode oscillation due to the influences of manufacturing errors.

Because of this, it is preferable that the position of the phase shift portion 121a be close to the center of the distributed feedback active region 131 within a range in which the influences of manufacturing errors can be sufficiently inhibited, and an optimum location thereof differs depending on a resonator length and a coupling coefficient of a diffraction grating, but the range is 0.5<α<1. For example, it can be set to α=0.75.

Further, when the phase shift portion 121a is closer to the second distributed Bragg reflector 132b than the center of the distributed feedback active region 131, an electric field is localized in the phase shift portion 121a, and as a result, light is emitted from the second distributed Bragg reflector 132b side. In a case in which light is emitted from the first distributed Bragg reflector 132a side, the length of the second distributed Bragg reflector 132b in the waveguide direction is set sufficiently large that a correlation of L₂(1−x)+L₃>xₚₛ is satisfied, and light is extracted only from the first distributed Bragg reflector 132a.

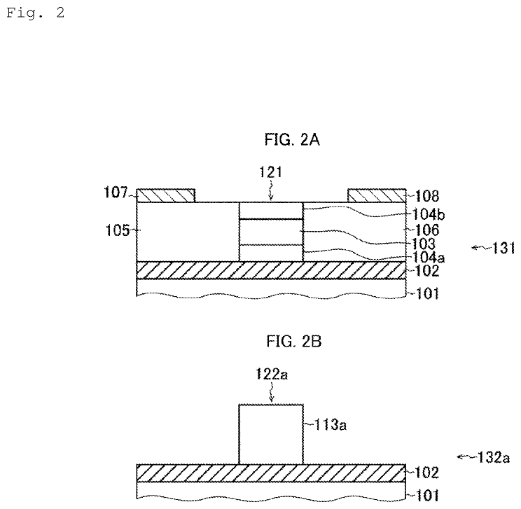

Hereinafter, the semiconductor laser according to the embodiment will be described in more detail with reference to FIGS. 2A and 2B. Also, FIG. 2A shows a cross-section of the distributed feedback active region 131 perpendicular to the waveguide direction. Further, FIG. 2B shows a cross-section of the first distributed Bragg reflector 132a perpendicular to the waveguide direction.

The distributed feedback active region 131, the first distributed Bragg reflector 132a, and the second distributed Bragg reflector 132b are formed on the same substrate 101. The distributed feedback active region 131 includes an n-type semiconductor layer 105 and a p-type semiconductor layer 106 formed in contact with the active layer 103.

In the present example, the n-type semiconductor layer 105 and the p-type semiconductor layer 106 are disposed in a plane direction of the substrate 101, and these are formed on the substrate 101 in contact with side surfaces of the active layer 103 in a direction perpendicular to the waveguide direction. Further, an n-type electrode 107 electrically connected to the n-type semiconductor layer 105 and a p-type electrode 108 electrically connected to the p-type semiconductor layer 106 are provided. In the present example, a current is injected in the plane direction (lateral direction) of the substrate 101. In addition, the n-type electrode 107 can also be formed on the n-type semiconductor layer 105 via an n-type contact layer in which n-type impurities are introduced at a higher concentration. Similarly, the p-type electrode 108 can be formed on the p-type semiconductor layer 106 via a p-type contact layer in which p-type impurities are introduced at a higher concentration.

Also, a lower clad layer 102 is formed on the substrate 101, and the active layer 103 is formed on the lower clad layer 102. The first core layer 113a is also formed on the lower clad layer 102. Further, the active layer 103 is interposed between a semiconductor layer 104a and a semiconductor layer 104b in a vertical direction when viewed from the substrate 101. Also, a laminated structure of the semiconductor layer 104a, the active layer 103, and the semiconductor layer 104b is interposed between the n-type semiconductor layer 105 and the p-type semiconductor layer 106. The p-type semiconductor layer 106 and the n-type semiconductor layer 105 are formed to interpose the active layer 103 in a direction parallel to the plane of the substrate 101. Further, in the present example, the first diffraction grating 121 is formed on an upper surface of the semiconductor layer 104b.

Here, the active layer 103 is formed in contact with the upper portion of the semiconductor layer 104a, and the semiconductor layer 104b is formed in contact with the upper portion of the active layer 103. Further, the n-type semiconductor layer 105 and the p-type semiconductor layer 106 are formed in contact with a side portion of the laminated structure of the semiconductor layer 104a, the active layer 103, and the semiconductor layer 104b. Also, the n-type semiconductor layer 105 and the p-type semiconductor layer 106 are not formed in the first distributed Bragg reflector 132a.

In the distributed feedback active region 131 according to the embodiment, a current is injected into the active layer 103 in a direction parallel to the plane of the substrate 101. Also, the n-type electrode 107 and the p-type electrode 108 are not formed in the first distributed Bragg reflector 132a and the second distributed Bragg reflector 132b.

The substrate 101 is made of, for example, silicon. The lower clad layer 102 is made of, for example, silicon oxide (SiO₂) and has a thickness of 2 μm. Further, the active layer 103 has, for example, a quantum well structure having a thickness of 150 nm in which well layers and barrier layers made of InGaAsP are alternately laminated. Also, a width of the active layer 103 is about 0.7 μm. Also, a total thickness of the semiconductor layer 104a, the active layer 103, and the semiconductor layer 104b is 250 nm. In addition, the n-type semiconductor layer 105 and the p-type semiconductor layer 106 also both have a thickness of 250 nm. A light-emitting wavelength of the active layer 103 having the quantum well structure is 1.55 μm. Also, the Bragg wavelength of the first diffraction grating 121 is 1.55 μm.

Further, for example, the semiconductor layer 104a and the semiconductor layer 104b are composed of undoped InP (i-InP). In addition, one n-type semiconductor layer 105 interposing the active layer 103 is composed of n-type InP (n-InP) doped with Si by about 1×10¹⁸ cm⁻³, and the other p-type semiconductor layer 106 is composed of p-type InP (p-InP) doped with Zn by about 1×10¹⁸ cm⁻³.

Also, the first core layer 113a and the second core layer 113b are composed of undoped InP (i-InP), have a width of about 1.5 μm, and have a thickness of 250 nm. Further, although not shown, the n-type contact layer and the p-type contact layer can be composed of, for example, InGaAs.

In the above-mentioned semiconductor laser, the lower clad layer 102 made of silicon oxide having a low refractive index is formed in a lower portion of a layer of InP having a high refractive index, and air having a low refractive index is formed in an upper portion thereof. As a result, strong light confinement in the active layer 103, the first core layer 113a, and the second core layer 113b is realized, which is advantageous for low power operation of the laser. Further, since the diffraction grating is formed to have a high refractive index difference between the InP layer and the air layer, a high coupling coefficient exceeding 1000 cm⁻¹ can be realized. In addition, according to the above configuration, optical waveguides of the first distributed Bragg reflector 132a and the second distributed Bragg reflector 132b do not need to be regrown and can be easily manufactured. In this case, a difference in effective refractive index between the distributed feedback active region 131 and the distributed Bragg reflectors is different, but, as will be described later, stable single-mode oscillation can be realized even in consideration of manufacturing errors.

The first distributed Bragg reflector 132a and the second distributed Bragg reflector 132b can also be made of embedded waveguides. In this case, for example, a core is composed of InGaAsP having a composition of a non-gain medium, and a clad covering the core is composed of InP.

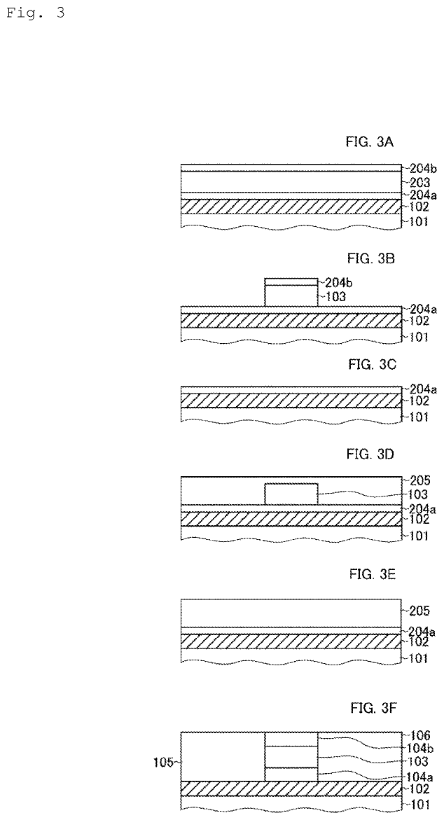

Hereinafter, a method for manufacturing the semiconductor laser according to the embodiment will be briefly described with reference to FIGS. 3A to 3F. FIGS. 3A to 3F are configuration diagrams showing a state during manufacture of the semiconductor laser according to the embodiment, and schematically show a cross-section of the distributed feedback active region 131.

For example, first, the substrate (silicon substrate) 101 having the lower clad layer 102 made of silicon oxide is prepared. For example, the lower clad layer 102 is formed by thermally oxidizing a main surface of the substrate 101.

On the other hand, a sacrificial layer made of InGaAs, a compound semiconductor layer 204b made of undoped InP, a compound semiconductor layer 203 serving as the active layer 103, a compound semiconductor layer 204a made of undoped InP, and a compound semiconductor layer serving as the first core layer 113a and the second core layer 113b are epitaxially grown on an InP substrate. For example, each layer may be grown using a well-known metal organic vapor phase growth method.

Next, the uppermost surface of the epitaxially grown substrate and a surface of the lower clad layer 102 of the substrate 101 described above are directly bonded using a known wafer bonding technique, and then the InP substrate and the sacrificial layer are removed. As a result, as shown in FIG. 3A, in the distributed feedback active region 131, the lower clad layer 102, the compound semiconductor layer 204a, the compound semiconductor layer 203, and the compound semiconductor layer 204b are formed on the substrate 101.

Next, by performing wet etching, dry etching, and the like using a resist pattern as a mask, which is produced using a known photolithography technique, the compound semiconductor layer 204a, compound semiconductor layer 203, compound semiconductor layer 204b, which are grown, and the like are patterned, and as shown in FIG. 3B, a striped structure of the distributed feedback active region 131 including the active layer 103 is formed. Also, at this point, the semiconductor layer 204a for regrowth is formed over the entire area of the lower clad layer 102. Further, the compound semiconductor layer 204b remains on the active layer 103. As shown in FIG. 3C, the first distributed Bragg reflector 132a and the second distributed Bragg reflector 132b are in a state without the active layer 103. Also, after each pattern is formed, the resist pattern is removed.

Next, as shown in FIG. 3D, a compound semiconductor layer 205 made of undoped InP is regrown from the semiconductor layer 204a around the active layer 103. By the regrowth, the compound semiconductor layer 204b on the active layer 103 becomes integrated with the compound semiconductor layer 205. The first distributed Bragg reflector 132a and the second distributed Bragg reflector 132b are in a state in which the compound semiconductor layer 205 is formed on the compound semiconductor layer 204a, as shown in FIG. 3E.

Next, for example, using an ion implantation method, n-type impurities and p-type impurities are selectively introduced into regions on both sides of the active layer 103, and thus in the distributed feedback active region 131, as shown in FIG. 3F, the n-type semiconductor layer 105 and the p-type semiconductor layer 106 are formed, and the semiconductor layer 104a and the semiconductor layer 104b are formed. At this stage, the compound semiconductor layer 205 remains in the regions interposing the distributed feedback active region 131 (not shown) in the waveguide direction.

Next, the first diffraction grating 121 is formed on the surface of the semiconductor layer 104b. For example, the first diffraction grating 121 may be formed by using a resist pattern as a mask, which is formed through lithography using electron beam exposure, and patterning using predetermined etching. Similarly, the second diffraction grating 122a and the third diffraction grating 122b are formed in the regions of the first distributed Bragg reflector 132a and the second distributed Bragg reflector 132b of the compound semiconductor layer 205 in the regions interposing the distributed feedback active region 131 (not shown) in the waveguide direction. At this stage, the first core layer 113a and the second core layer 113b are not formed.

Next, the compound semiconductor layer 205 in the regions interposing the distributed feedback active region 131 in the waveguide direction is patterned in the same manner as described above, and thus the first core layer 113a and the second core layer 113b are formed at portions at which the second diffraction grating 122a and the third diffraction grating 122b are formed. According to this configuration, since the first core layer 113a and the second core layer 113b of the first distributed Bragg reflector 132a and the second distributed Bragg reflector 132b are formed with the compound semiconductor layer 205 used for forming the n-type semiconductor layer 105 and the p-type semiconductor layer 106 for current injection, the process can be simplified. Then, the n-type electrode 107 is formed on the n-type semiconductor layer 105, and the p-type electrode 108 is formed on the p-type semiconductor layer 106.

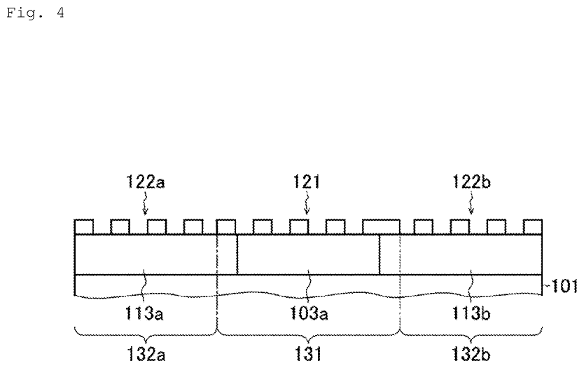

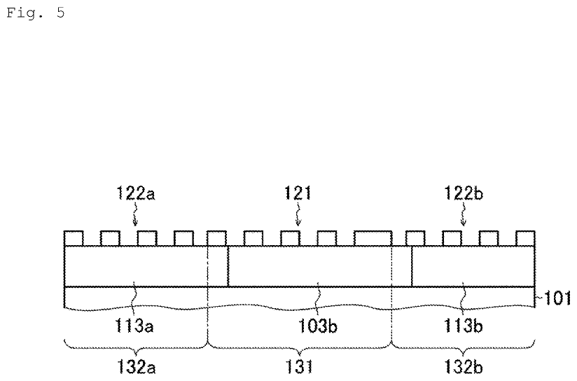

Hereinafter, the position of the phase shift portion 121a and the length of the second distributed Bragg reflector 132b in the waveguide direction will be described in more detail. First, problems that may occur due to manufacturing errors will be described with reference to FIGS. 4 and 5. Also, in FIGS. 4 and 5, for convenience of explanation, the lengths of the first distributed Bragg reflector 132a and the second distributed Bragg reflector 132b in the waveguide direction are shown to be about the same.

For example, as a manufacturing error 1, as shown in FIG. 4, an active layer 103a having a length in the waveguide direction shorter than that of the distributed feedback active region 131 (first diffraction grating 121) may be formed. In this case, a part of the first core layer 113a and the second core layer 113b enters a region of the first diffraction grating 121 (distributed feedback active region 131). In this way, in the part of the first core layer 113a and the second core layer 113b, which are non-gain media, entering the distributed feedback active region 131, light reflection on the second diffraction grating 122a and the third diffraction grating 122b does not occur. As a result, when the manufacturing error as described above occurs, a phase change occurs and the oscillation mode becomes unstable.

Further, as a manufacturing error 2, as shown in FIG. 5, the active layer 103b may be formed at a position deviated in the waveguide direction. In this case, the position of the first diffraction grating 121 with respect to the active layer 103b deviates, and the position of the phase shift portion changes. In this state, since an electric field distribution in a resonator changes, the oscillation mode becomes unstable depending on a state of deviation.

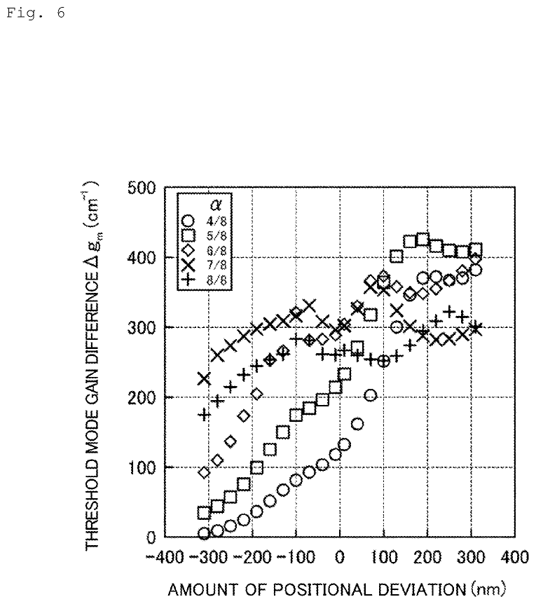

In actual manufacturing of the laser, it is necessary to consider that both manufacturing error 1 and manufacturing error 2 occur. Here, FIG. 6 shows a relationship between an amount of deviation from a design value of the position of the active layer in the waveguide direction and a difference between threshold mode gains in a case in which the length of the active layer in the waveguide direction is formed to be 500 nm shorter in total than the design value with respect to the center of the distributed feedback active region in the waveguide direction evenly toward the first distributed Bragg reflector side and the second distributed Bragg reflector side, respectively.

Further, the difference between the threshold mode gains is a threshold mode gain difference “Δgₘ=gₘ(2)−gₘ(1)” between the smallest mode and the second smallest mode. Also, in FIG. 6, the position of the phase shift portion is indicated by using α. α=4/8 indicates that it is in the center of the distributed feedback active region, and α=8/8 indicates that it is at the boundary between the distributed feedback active region and the second distributed Bragg reflector. In addition, the length of the distributed feedback active region in the waveguide direction is set to 20 μm, the length of the first distributed Bragg reflector in the waveguide direction is set to 10 μm, and the length of the second distributed Bragg reflector in the waveguide direction is set to 50 μm. Further, a state in which the active layer protrudes toward the second distributed Bragg reflector side is defined as a plus.

Further, equivalent refractive indexes of the first distributed Bragg reflector and the second distributed Bragg reflector are 2.5, and an equivalent refractive index of the distributed feedback active region is 2.7. Also, the coupling coefficient of the diffraction gratings in the first distributed Bragg reflector and the second distributed Bragg reflector is 1100 cm⁻¹. Also, the coupling coefficient of the diffraction grating in the distributed feedback active region is 1000 cm⁻¹. In addition, the Bragg wavelengths are calculated as 1550 nm. A phase shift amount of the phase shift portion is set to λ/4.

As shown in FIG. 6, in a case in which the active layer deviates 300 nm toward the first distributed Bragg reflector (—300), the difference is Δgₘ<50 cm⁻¹ in the case of α<6/8, and thus there is a risk of multi-mode oscillation. For this reason, it can be seen that by setting α≥6/8, stable single-mode oscillation can be realized against manufacturing errors.

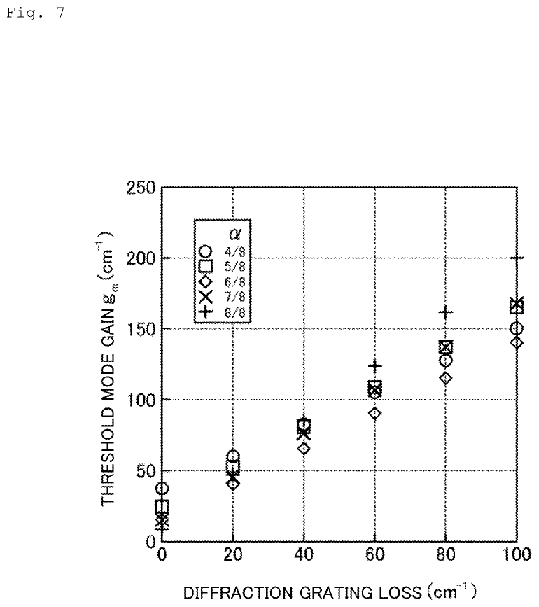

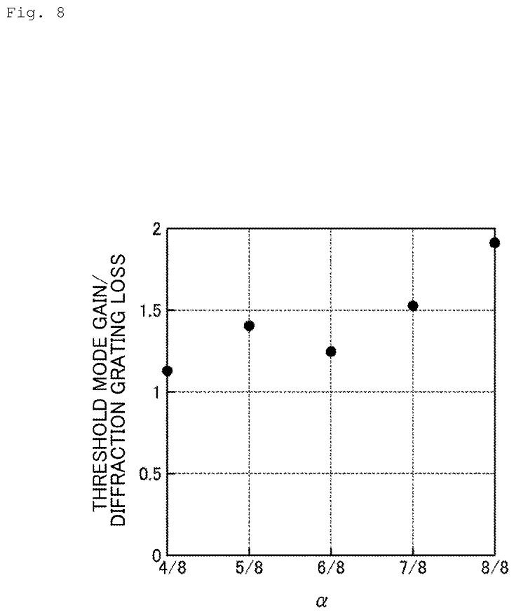

FIG. 7 shows a relationship between the diffraction grating loss and the threshold mode gain (gₘ). It is assumed that the diffraction grating loss is evenly distributed over the distributed feedback active region, the first distributed Bragg reflector, and the second distributed Bragg reflector. Further, FIG. 8 shows a relationship between an inclination of the graph in FIG. 7 and a that defines the position xₚₛ of the phase shift portion. As shown in FIG. 8, it can be seen that the larger a is, the higher the threshold gain is due to the diffraction grating loss.

From the results shown in FIG. 6, it can be seen that the larger a is (the closer the position of the phase shift portion is to the second distributed Bragg reflector side), the more the influences of the manufacturing errors can be inhibited. On the other hand, as shown in FIGS. 7 and 8, the larger a is, the stronger the influence of the diffraction grating loss is. Considering these results, α=6/8 is set such that the influences of the manufacturing errors can be sufficiently inhibited, whereby multi-mode oscillation due to the influences of manufacturing errors can be prevented while inhibiting an increase in the threshold gain due to the diffraction grating loss.

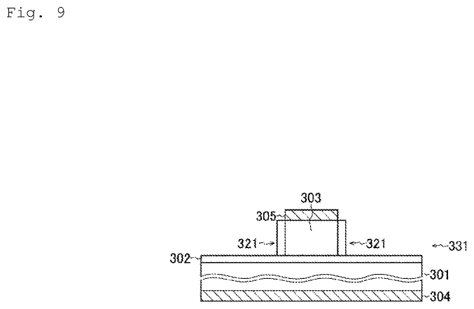

Incidentally, although the case in which the current is injected in the direction parallel to the plane of the substrate has been described as an example in the above description, the present invention is not limited thereto and may be configured such that the current is injected in the direction perpendicular to the plane of the substrate. For example, as shown in FIG. 9, in the distributed feedback active region 331, the width of the active layer 302 can be formed wider than that of the core layer 312a, and the p-type semiconductor layer 303 can be formed to have the same width as the core layer 312a. In this case, a diffraction grating is not formed in the active layer 302, but the first diffraction grating 321 is formed on the side surface of the p-type semiconductor layer 303 in the waveguide direction. Also, in this case, although not shown, a phase shift portion is provided on the first diffraction grating 321. Further, an n-type electrode 304 is formed on a back surface of the substrate 301 made of an n-type semiconductor, and a p-type electrode 305 is formed on the p-type semiconductor layer 303. In this case, the p-type semiconductor layer 303 and the substrate (n-type semiconductor layer) 301 are formed to interpose the active layer 302 from above and below.

As described above, according to the present invention, the length of the first distributed Bragg reflector L₁, the length of the distributed feedback active region L₂, the length of the second distributed Bragg reflector L₃, and the position xₚₛ of the phase shift portion are set to satisfy the correlations of xₚₛ=L₁+L₂×α, L₂(1−α)+L₃>xₚₛ, and 0.5<α<1, and thus the phase shift distributed feedback laser having the distributed Bragg reflectors provided on both sides can inhibit influences of manufacturing errors and perform stable single-mode oscillation without increasing the threshold gain.

Further, it is clear that the present invention is not limited to the embodiments described above, and many modifications and combinations can be carried out by those having ordinary knowledge in the art within the technical idea of the present invention. For example, the waveguide structure can be applied to a ridge type and a high mesa type waveguide structures. Further, the substrate is composed of InP in the above description, but the present invention is not limited to this, and the substrate may be composed of semiconductors such as GaAs and GaN. In addition, the active layer is not limited to InGaAsP and can be composed of semiconductors such as InGaAlAs, AlGaAs, and InGaN.

### REFERENCE SIGNS LIST

101 Substrate
102 Lower clad layer
103 Active layer
104a Semiconductor layer
104b Semiconductor layer
105 n-type semiconductor layer
106 p-type semiconductor layer
107 n-type electrode
108 p-type electrode
113a First core layer
113b Second core layer
121 First diffraction grating
121a Phase shift portion
122a Second diffraction grating
122b Third diffraction grating
131 Distributed feedback active region
132a First distributed Bragg reflector
132b Second distributed Bragg reflector.

1-4. (canceled)

5. A semiconductor laser comprising:
an active layer on a substrate;
a distributed feedback active region along the active layer, the distributed feedback active region including a first diffraction grating, the first diffraction grating including a phase shift portion configured to shift a phase of a diffraction grating; and
a first distributed Bragg reflector and a second distributed Bragg reflector which are disposed continuously with the distributed feedback active region with the distributed feedback active region interposed therebetween;
wherein the first distributed Bragg reflector includes:
a first core layer disposed continuously with the active layer in a waveguide direction and has a refractive index different from that of the active layer; and
a second diffraction grating along the first core layer;
wherein the second distributed Bragg reflector includes:
a second core layer disposed continuously with the active layer in the waveguide direction, the second distributed Bragg reflector being on a side opposite to the first core layer with the active layer interposed therebetween, and the second distributed Bragg reflector having a refractive index different from that of the active layer; and
a third diffraction grating disposed along the second core layer; and
wherein a length L1 of the first distributed Bragg reflector in the waveguide direction, a length L2 of the distributed feedback active region in the waveguide direction, a length L3 of the second distributed Bragg reflector in the waveguide direction, and a position xₚₛ of the phase shift portion in the waveguide direction with an end portion thereof on the first distributed Bragg reflector side set as an origin are set to satisfy: xₚₛ=L₁+L₂×α, L₂(1−α)+L₃>xₚₛ, and 0.5<α<1.

6. The semiconductor laser according to claim 5, wherein the distributed feedback active region includes a p-type semiconductor layer and an n-type semiconductor layer in contact with the active layer, an n-type electrode connected to the n-type semiconductor layer, and a p-type electrode connected to the p-type semiconductor layer.

7. The semiconductor laser according to claim 6, wherein the p-type semiconductor layer and the n-type semiconductor layer are disposed on the substrate in contact with a side surface of the active layer in a direction perpendicular to the waveguide direction.

8. The semiconductor laser according to claim 6, wherein the p-type semiconductor layer and the n-type semiconductor layer interpose the active layer from above and below.

9. A method of forming a semiconductor laser, the method comprising:
forming an active layer on a substrate;
forming a distributed feedback active region along the active layer, the distributed feedback active region including a first diffraction grating, the first diffraction grating including a phase shift portion configured to shift a phase of a diffraction grating; and
forming a first distributed Bragg reflector and a second distributed Bragg reflector continuously with the distributed feedback active region with the distributed feedback active region interposed therebetween;
wherein the first distributed Bragg reflector includes:
a first core layer formed continuously with the active layer in a waveguide direction and has a refractive index different from that of the active layer; and
a second diffraction grating along the first core layer;
wherein the second distributed Bragg reflector includes:
a second core layer formed continuously with the active layer in the waveguide direction, the second distributed Bragg reflector being on a side opposite to the first core layer with the active layer interposed therebetween, and the second distributed Bragg reflector having a refractive index different from that of the active layer; and
a third diffraction grating disposed along the second core layer; and
wherein a length L1 of the first distributed Bragg reflector in the waveguide direction, a length L2 of the distributed feedback active region in the waveguide direction, a length L3 of the second distributed Bragg reflector in the waveguide direction, and a position xₚₛ of the phase shift portion in the waveguide direction with an end portion thereof on the first distributed Bragg reflector side set as an origin are set to satisfy: xₚₛ=L₁+L₂×α, L₂(1−α)+L₃>xₚₛ, and 0.5<α<1.

10. The method according to claim 9, wherein the distributed feedback active region includes a p-type semiconductor layer and an n-type semiconductor layer in contact with the active layer, an n-type electrode connected to the n-type semiconductor layer, and a p-type electrode connected to the p-type semiconductor layer.

11. The method according to claim 10, wherein the p-type semiconductor layer and the n-type semiconductor layer are disposed on the substrate in contact with a side surface of the active layer in a direction perpendicular to the waveguide direction.

12. The method according to claim 10, wherein the p-type semiconductor layer and the n-type semiconductor layer interpose the active layer from above and below.
